(19) United States
(12) Patent Application Publication
(10) Pub. No.: US 2015/0036116 A1
(43) Pub. Date: Feb. 5, 2015

(54) APERTURE FOR PHOTOLITHOGRAPHY

(71) Applicant: UNITED MICROELECTRONICS CORP., Hsin-Chu City (TW)

(72) Inventors: Te-Hsien Hsieh, Kaohsiung City (TW); Shih-Ming Kuo, Tainan City (TW); Ming-Jui Chen, Hsinchu City (TW); Cheng-Te Wang, Hsinchu County (TW); Jing-Yi Lee, Tainan City (TW)

(73) Assignee: UNITED MICROELECTRONICS CORP., Hsin-Chu City (TW)

(21) Appl. No.: 13/957,436

(22) Filed: Aug. 2, 2013

(51) Int. Cl. G03F 7/20

(52) U.S. Cl. CPC G03F 7/7015
USPC 355/71

(57) ABSTRACT

An aperture is configured to be disposed between an illumination source and a semiconductor substrate in a photolithography system. The aperture includes a light-transmission portion with a non-planar thickness profile to compensate the discrepancy of wave-fronts of the light beams of different orders.

### BACKGROUND OF THE INVENTION

1. Field of the Invention

The field of invention relates generally to the field of semiconductor integrated circuit manufacturing and more specifically, but not exclusively, to the implementation of an aperture in a photolithography system.

2. Description of the Prior Art

Patterns may be fabricated on a semiconductor (e.g., a silicon wafer) by transmitting beams of light through a reticle onto a surface of the semiconductor. To produce patterns with extremely small pitches (i.e., the distances between lines or features), a series of resolution enhancement techniques (RETs) have been employed to enhance a resolution limit of optical lithography while providing a manufacturable depth of focus (DOF). A principle RET applied in low k₁ lithography in the fabrication of semiconductor devices is the off-axis illumination (OAI), which has been proved to be effective in increasing the DOF while improving the image resolution. Even though the OAI may be effective for a narrow range of applications, for example a pattern layout with a densely packed series of repeated features, the process window for layouts of features combining regions of isolated and dense patterns may be vanishingly small.

One method for enhancing the lithography process window is to use an illumination aperture in an illuminator assembly of a projector system. Referring now to FIG. 1, the basic components that make up a projection system for photolithography are schematically illustrated. A light beam 105 is condensed by an illuminator lens 110 so that a reticle 115 that includes features 120 is uniformly illuminated. Most of the light beam 105 passes straight on as the zero order diffraction maximum 125, while first order diffraction maxima 130 and higher order diffraction maxima 135 are diffracted off to the side. These are then focused by a projection lens 140 onto a focal plane 145. Since no information (other than the overall brightness) is contained in the zero order diffraction maximum 125, it is imperative that at least some of the higher order beams, such as the first order diffraction maxima 130 and the higher order diffraction maxima 135, contribute to the image. This necessarily widens the angle of the focusing cone, resulting in a reduced DOF.

In FIG. 2, the basic setup of FIG. 1 has been modified so that the light beam 105 is blocked from the center of the illuminator lens 110 by an illumination aperture filter 112, as being limited to coming in obliquely (off-axis). The result of this configuration is that the zero order diffraction maximum 125 is forced over the to the edge of projection lens 140 while first order diffraction maxima 130 pass (approximately) through the center of the projection lens 140, thereby allowing a narrower angle for the focusing cone, with a corresponding increase in the DOF.

In FIG. 3, a different modification of the basic setup of FIG. 1 has been introduced; in this new configuration, a phase-type filter 150 is placed on a pupil plane of the projection lens 140. Its effect is to change the phase of the first order diffraction maxima 130 and the higher order diffraction maxima 135 by 180 degrees relatively to that of the zero order diffraction maxima 125. This results in an increase of the DOF for dense patterns.

Although the above-mentioned prior arts are able to enhance a resolution limit of the optical lithography while providing an increased DOF, the problem of wave-front discrepancy between the diffracted light beams with different orders still exists. This wave-front discrepancy may impact the resolution of the photolithography system.

### SUMMARY OF THE INVENTION

Accordingly, in the present invention, a novel aperture is provided in the photolithography system to compensate the discrepancy of the wave-fronts of the light beams with different orders. The design of the non-planar thickness profiles of the aperture can render the wave-fronts of the light beams with different orders to be the same on the image/focal plane.

One object of the present invention is to provide an aperture to be disposed between an illumination source and a semiconductor substrate in an optical lithography system. The aperture includes a first light-transmission portion with a non-planar thickness profile.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the embodiments, and are incorporated in and constitute apart of this specification. The drawings illustrate some of the embodiments and, together with the description, serve to explain their principles. In the drawings:

FIG. 1 is a schematic illustration of a photolithography system in prior art.

FIG. 2 is an alternate embodiment of the photolithography system of FIG. 1 in prior art, in which an illumination aperture filter with off-axis illumination has been introduced.

FIG. 3 illustrates another embodiment of the photolithography system of FIG. 1 including a phase-type pupil filter in prior art.

FIG. 4 illustrates a photolithography system without the compensation of an aperture in accordance with one embodiment of present invention.

FIG. 5 illustrates a photolithography system with the compensation of an aperture in accordance with another embodiment of present invention.

FIG. 6 is a cross-sectional view of an aperture in accordance with one embodiment of present invention.

FIG. 7 is a cross-sectional view of an aperture in accordance with another embodiment of present invention.

FIG. 8 is a cross-sectional view of an aperture in accordance with still another embodiment of present invention.

FIG. 9 is a cross-sectional view of an aperture with an opaque pupil portion in accordance with still another embodiment of present invention.

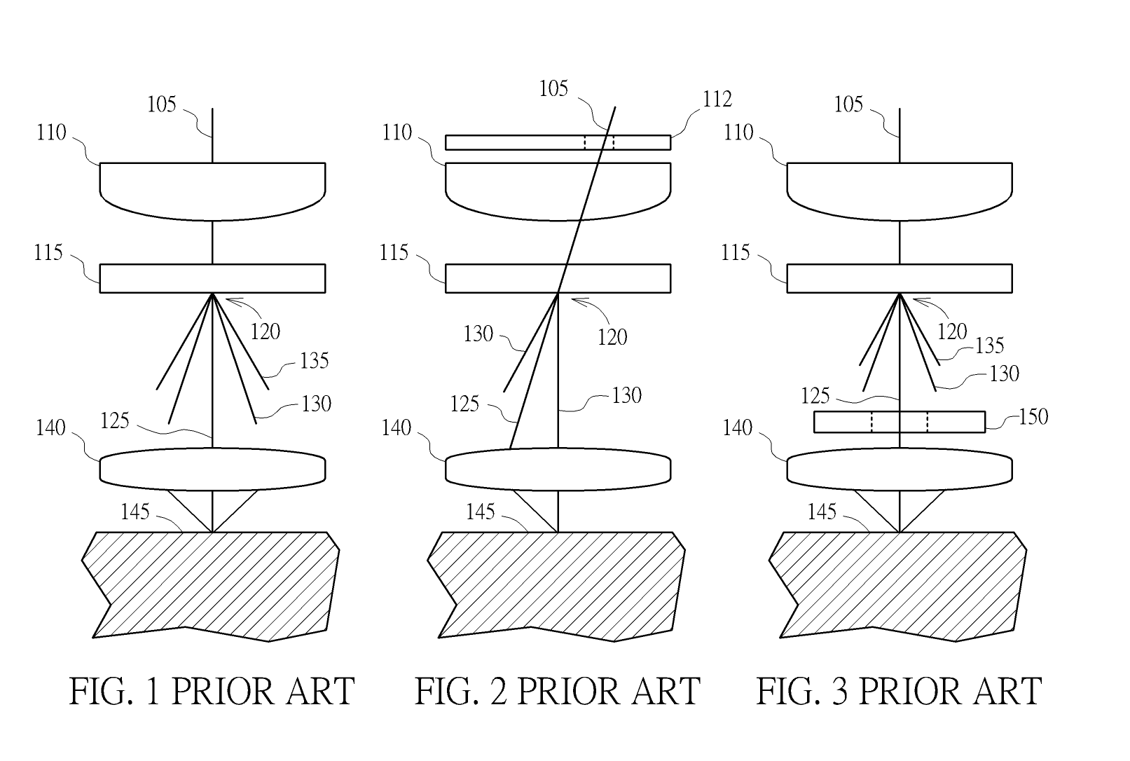

It should be noted that all the figures are diagrammatic. Relative dimensions and proportions of parts of the drawings have been shown exaggerated or reduced in size, for the sake of clarity and convenience in the drawings. The same reference signs are generally used to refer to corresponding or similar features in modified and different embodiments.

### DETAILED DESCRIPTION

In the following detailed description of the present invention, reference is made to the accompanying drawings which form a part hereof and is shown byway of illustration and specific embodiments in which the invention may be practiced. These embodiments are described in sufficient details to enable those skilled in the art to practice the invention. Other embodiments may be utilized and structural, logical, and electrical changes may be made without departing from the scope of the present invention. The following detailed description, therefore, is not to be taken in a limiting sense, and the scope of the present invention is defined by the appended claims.

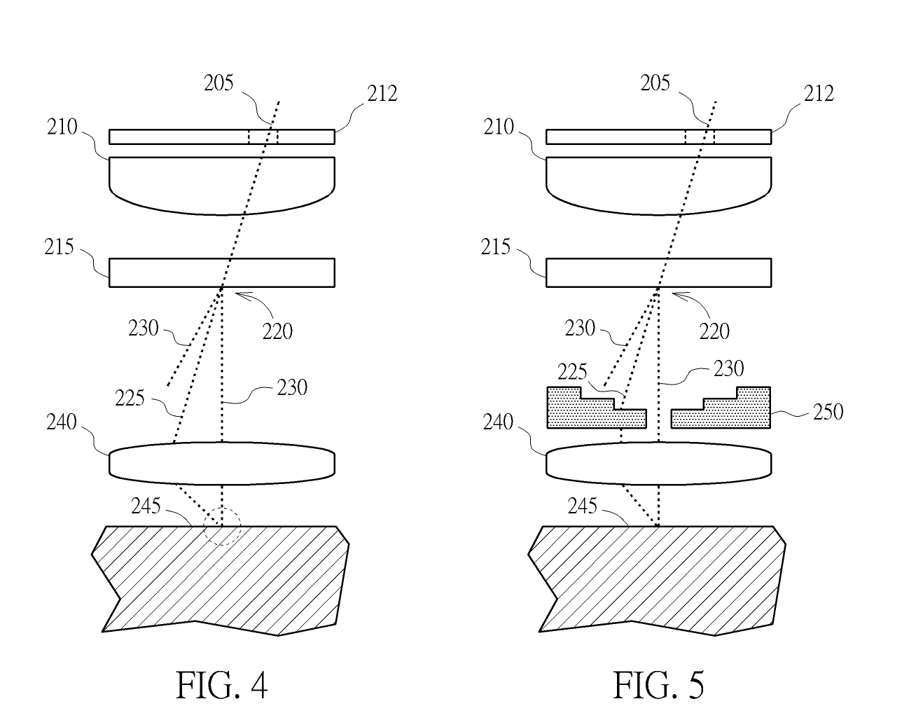

First, please refer to FIG. 4, which is a schematic view illustrating a photolithography system without the compensation of an aperture in accordance with one embodiment of present invention. As shown in FIG. 4, the photolithography system includes an illumination lens 210, a projection lens 240, a reticle 215 that includes circuit features disposed between the illumination lens 210 and the projection lens 240, and an illumination aperture filter 210 disposed in front of the illumination lens 210. The light beam 205 originating from an illumination source (not shown) is blocked from the center of illuminator lens 210 by the illumination aperture filter 212 and being limited to coming in obliquely (off-axis). After being condensed by the illuminator lens 210 and passing through the reticle 215, the light beam 205 is diffracted and divided into multiple light beams with different order diffraction maxima. For the simplicity of the illustrations, only the zero order diffraction maximum 225 and the first order diffraction maximum 230 are shown in FIGS. 4 and 5. In reality, the light beam 205 includes other higher order branches.

The light beam 205 is denoted by the dotted line in this embodiment, wherein each dot stands for the wave peak of the light beam 205 which is the locus of the points having the same phase. In this configuration, as shown in FIG. 4, the light beam of the zero order diffraction maximum 225 is forced over to the edge of projection lens 240, while the light beam of first order diffraction maxima 230 passes approximately through the center of the projection lens 240. Due to the diffraction of different orders, the wave-front of the zero order diffraction maximum 225 and the wave-front of the first order diffraction maximum 230 don't arrive simultaneously on the same image/focal plane 245, e.g., the surface of the wafer. This phenomenon is called as the wave-front (phase) discrepancy. The wave-front discrepancy is denoted in FIG. 4 by the dots of the light beams of the zero order diffraction maximum 225 and the first order diffraction maximum 230 being both not exactly positioned on the focal plane 245. This wave-front discrepancy may impact the resolution of the photolithography system, thus a solution is required to solve this issue.

Please refer now to FIG. 5, which is a schematic view illustrating a photolithography system with the compensation of an aperture in accordance with one embodiment of the present invention. In this exemplary embodiment, as shown in FIG. 5, an aperture 250 is configured to be disposed between the reticle 215 and the projection lens 240 in the photolithography system for compensating the wave-front discrepancy of the diffracted light beams of different orders. The aperture 250 of the present invention may be a transparent plate or disk with non-planar thickness profiles. The thickness profile of the aperture 250 is designed and predetermined according to the pattern of the reticle 215 and the illumination aperture filter 212 used in the system. In one of the embodiments, the thickness profile of the aperture 250 decreases from the edge of the aperture 250 to the central axis of the aperture 250. Detailed features of the thickness profile will be illustrated hereafter in the following embodiments. With the compensation of the aperture 250 having a non-planar and predetermined thickness profile, the wave-front of the diffracted light beam 205 of different orders, including the zero order diffraction maximum 225 and the first order diffraction maximum 230, would be simultaneously on the same focal plane 245. This wave-front compensation is denoted in FIG. 5 by the dots of the light beams of the zero order diffraction maximum 225 and the first order diffraction maximum 230 being both exactly positioned on the focal plane 245.

Please note that the part arrangement shown in the figures is only an exemplary embodiment of present invention. In real implementation, the aperture 250 is not limited to be disposed only between the reticle 215 and projection lens 240. Generally, the aperture 250 is designed to be disposed between the illumination source (not shown) and the semiconductor substrate. For example, the aperture 250 may be configured to be disposed between the illumination source (not shown) and the illumination lens 210 or between the reticle 215 and projection lens 240, depending on the requirement of the photolithographic tool and process.

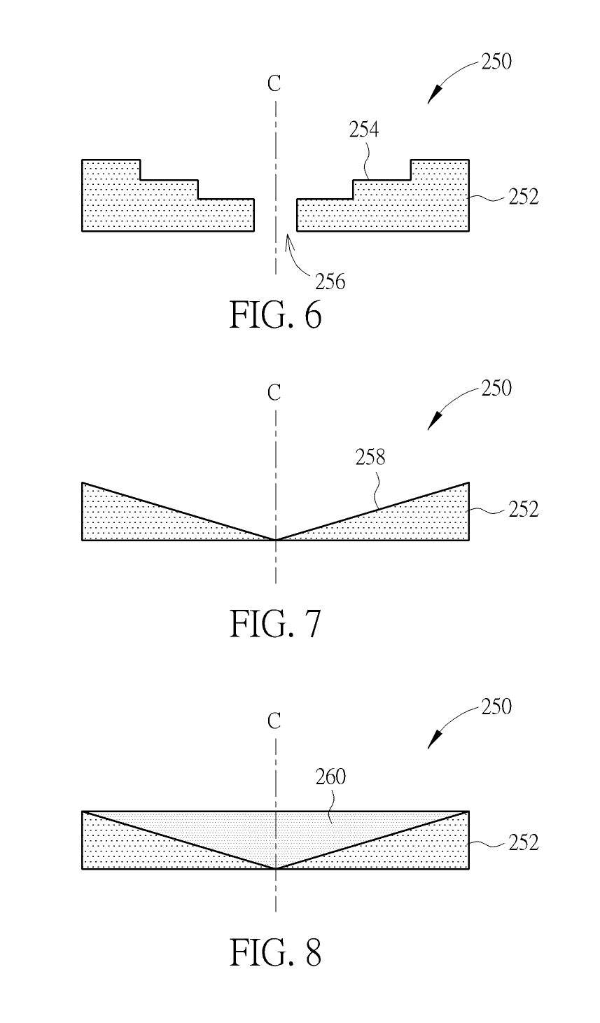

Please refer now to FIGS. 6-9, which are cross-sectional views of the exemplary aperture 250 with different thickness profiles or variations. As shown in FIG. 6, the aperture 250 includes a first light-transmission portion 252. The light-transmission portion 252 may be a transparent plate or disk body with a non-planar thickness profile, such as a stepped thickness profile shown in FIG. 6. In this embodiment, the thickness profile 254 of the aperture 250 is symmetric with respect to a central axis C of aperture 250, and more specifically, the thickness profile 254 steppedly and symmetrically decreases from the edge to the central axis C of the aperture 250. The aperture 250 may be additionally provided with an opening 256 formed in the center of the aperture to allow the light beams of specific orders (ex. the first order in this embodiment) to pass through without any diffraction. Please note that, in alternative embodiments, the number of openings 256 is not limited to one in the present invention. The aperture 250 may be provided with more than one opening 256 formed at predetermined positions.

Please refer to FIG. 7, which is a cross-sectional view of an aperture in accordance with another embodiment of the present invention. Unlike the one shown in FIG. 6, in this embodiment, as shown in FIG. 7, the thickness profile 258 of the first light-transmission portion 252 gradually and symmetrically decreases from the edge to the central axis C of the aperture 250.

Please refer to FIG. 8, which is a cross-sectional view of an aperture in accordance with still another embodiment of the present invention. In this embodiment, as shown in FIG. 8, the aperture 250 includes a first light-transmission portion 252 with a non-planar thickness profile 258 and a complementary second light-transmission portion 260. It is designed so that the refractive index of the second light-transmission portion 260 is different form the refractive index of the first light-transmission portion 252. For example, the light-transmission portion 260 and the second light-transmission portion 260 may be made of different materials, such as glass or plastic. Through the combination of the light-transmission portions with different refractive indexes, desired compensation of the wave-fronts may be achieved without utilizing complicated thickness profiles.

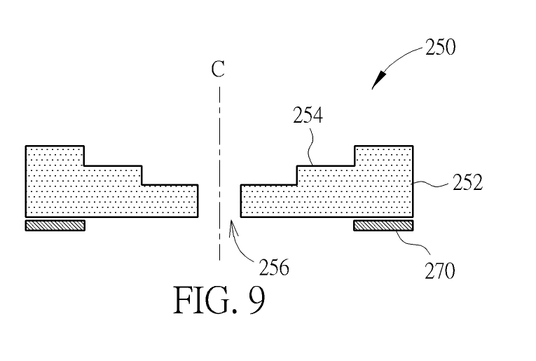

Please refer now to FIG. 9, which is a cross-sectional view of an aperture in accordance with still another embodiment of the present invention. In this embodiment, as shown in FIG. 9, the aperture 250 further includes an opaque pupil portion 270 under the aperture 250. The opaque pupil portion 270 is made of the material impenetrable by light, thus only the light beam at predetermined positions may be allow to pass. Through the opaque pupil portion 270, the phase of the light beams with first order diffraction maxima or the higher order diffraction maxima 135 may be further changed relatively to that of the zero order diffraction maxima, thereby resulting in an increase of the DOF for dense patterns.

Please note that in the present invention, the thickness profile is not limited to the ones shown in FIG. 6 and FIG. 7. In alternative embodiment, the aperture 250 may have other thickness profile, such as a thickness profile gradually increasing from the edge to the central axis C of the aperture 250. Alternatively, the shape of the aperture 250 may be irregular or asymmetric, depending on the pattern density and pitch of the reticle 215, the illumination aperture filter 212 or the opaque pupil portion 270 used in the system.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An aperture to be disposed between an illumination source and a semiconductor substrate in a photolithography system, wherein said aperture comprises a first light-transmission portion with a non-planar thickness profile.

2. An aperture to be disposed between an illumination source and a semiconductor substrate in a photolithography system according to claim 1, wherein said thickness profile gradually decreases from the edge of said aperture to a central axis of said aperture.

3. An aperture to be disposed between an illumination source and a semiconductor substrate in a photolithography system according to claim 1, wherein said thickness profile steppedly decreases from the edge of said aperture to a central axis of said aperture.

4. An aperture to be disposed between an illumination source and a semiconductor substrate in a photolithography system according to claim 1, wherein said thickness profile is symmetric with respect to a central axis of said aperture.

5. An aperture to be disposed between an illumination source and a semiconductor substrate in a photolithography system according to claim 1, wherein said aperture further comprises at least one opening formed in said aperture.

6. An aperture to be disposed between an illumination source and a semiconductor substrate in a photolithography system according to claim 5, wherein said at least one opening is formed in the center of said aperture.

7. An aperture to be disposed between an illumination source and a semiconductor substrate in a photolithography system according to claim 1, wherein the material of said first light-transmission portion comprises glass, plastic or quartz.

8. An aperture to be disposed between an illumination source and a semiconductor substrate in a photolithography system according to claim 1, wherein said aperture further comprises an opaque pupil portion disposed under said aperture.
